(19) United States
(12) Patent Application Publication
(10) Pub. No.: US 2025/0241134 A1
(43) Pub. Date: Jul. 24, 2025

(54) Display Device and Head-Mounted Display Apparatus

(71) Applicant: LG Display Co., Ltd., Seoul (KR)

(72) Inventors: Cheolhwan Lee, Suwon-si (KR); Yeonsuk Kang, Busan (KR); Chanwook Choi, Seoul (KR)

(21) Appl. No.: 18/815,727

(22) Filed: Aug. 26, 2024

(30) Foreign Application Priority Data
Jan. 22, 2024 (KR) 10-2024-0009549

(51) Int. Cl. H10K 59/122; G06F 1/16; H10K 59/80

(52) U.S. Cl. CPC H10K 59/122; G06F 1/163; H10K 59/873; H10K 59/876; H10K 59/8792

(57) ABSTRACT

A display device includes a substrate including a light-emissive area and a non-light-emissive area, a diode type bank located on the non-light-emissive area and separating a plurality of sub-pixels from each other, a light-emitting element disposed in each of the plurality of sub-pixels, and an encapsulation portion disposed on the light-emitting element.

### CROSS-REFERENCE TO RELATED APPLICATIONS

This application claims priority from Republic of Korea Patent Application No. 10-2024-0009549 filed on Jan. 22, 2024 in the Korean Intellectual Property Office, and all the benefits accruing therefrom under 35 U.S.C. 119, the contents of which in its entirety are herein incorporated by reference.

### BACKGROUND

### Field

The present disclosure relates to a display device for displaying an image and a head-mounted display apparatus including the same.

### Description of Related Art

Display devices are applied to various electronic devices such as TVs, mobile phones, laptops, and tablets. To this end, research is continuing to develop display devices that are thinner, lighter, and have lower power consumption.

Among the display devices that display various information using images, an organic light-emission display device (OLED) includes a plurality of pixel areas arranged in a display area where the image is displayed and a plurality of organic light-emitting elements corresponding to the plurality of pixel areas. Since the organic light-emitting element is a self-emitting element that emits light on its own, the organic light-emitting display device has a faster response speed, greater luminous efficiency, and luminance, and a large viewing angle, and superior contrast ratio and color gamut compared to the liquid crystal display device.

Recently, as demand for a head-mounted display apparatus (HMD) including the organic light-emission display device increases, research on the HMD is increasing. The head-mounted display apparatus is an image display device in a form of glasses or a helmet in which a focus is formed at a position close to the user's eyes. The head-mounted display apparatus may implement virtual reality (VR) or augmented reality (AR). In the virtual reality (VR) device, the viewer may view a 60-inch sized screen using a 1-inch sized display due to excellent user immersion thereof. For this purpose, the head-mounted display apparatus employs a high-resolution organic light-emission display device. However, research is underway on a solution to a problem arising from a small sub-pixel spacing used to implement the high-resolution display.

### SUMMARY

An embodiment of the present disclosure is to provide a display device including a diode type bank that may achieve excellent light-blocking characteristics.

An embodiment of the present disclosure is to provide a display device that may improve a color gamut of emitted light that is emitted from a light-emissive area by implementing a diode type bank with a low light transmittance.

An embodiment of the present disclosure is to provide a display device including a diode type the bank that may perform a function of an insulating film by replacing an organic insulating material or an inorganic insulating material in a display device with ultra-high resolution.

An embodiment of the present disclosure is to provide a head-mounted display apparatus including a display device including a diode type bank.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to one aspect of the present disclosure includes a substrate including a light-emissive area and a non-light-emissive area, a diode type bank located on the non-light-emissive area and separating a plurality of sub-pixels from each other, a light-emitting element disposed in each of the plurality of sub-pixels, and an encapsulation portion disposed on the light-emitting element.

A head-mounted display apparatus according to another aspect of the present disclosure includes a display device, a case for accommodating the display device therein, and a lens array that is disposed at one side of the case and displays an image output from the display device, and the display device includes a substrate including a light-emissive area and a non-light-emissive area, a diode type bank located on the non-light-emissive area and separating a plurality of sub-pixels from each other, a light-emitting element disposed in each of the plurality of sub-pixels, and an encapsulation portion disposed on the light-emitting element.

According to the embodiment of the present disclosure, the color gamut of emitted light that is emitted from the light-emitting element to the outside may be improved by including the diode type bank that may achieve the excellent light-blocking characteristics. As the color gamut improves, the light-emitting element may be driven with low power, thereby reducing the production energy.

According to the embodiment of the present disclosure, as the diode type bank is included, the problems that occur when using the bank including the organic or inorganic insulating material may be prevented.

According to the embodiment of the present disclosure, as the diode type bank is included, the color gamut deterioration of the display device caused by the emitted light emitted from the non-light-emissive area may be prevented.

According to the embodiment of the present disclosure, the head-mounted display apparatus including the display device including the diode type bank may provide the image with the ultra-high resolution having the excellent color gamut to the user, thereby further improving the user's sense of immersion in the image.

Effects of the present disclosure are not limited to the effects mentioned above, and other effects not mentioned will be clearly understood by those skilled in the art from the description below. In addition to the above effects, specific effects of the present disclosure are described together while describing specific details for carrying out the present disclosure.

### BRIEF DESCRIPTION OF DRAWINGS

FIG. 1 is a schematic perspective view of a display device according to an embodiment of the present disclosure.

FIG. 2 is a plan view schematically showing a portion of a display device according to an embodiment of the present disclosure.

FIG. 3 is an enlarged plan view of an area of one pixel among a plurality pixels in FIG. 2 according to an embodiment of the present disclosure.

FIG. 4 is a cross-sectional view along a line 4-4 in FIG. 3 according to an embodiment of the present disclosure.

FIG. 5 is an enlarged cross-sectional view of an area 5 in FIG. 4 according to an embodiment of the present disclosure.

FIG. 6 is an enlarged cross-sectional view of one sub-pixel according to Comparative Example.

FIGS. 7 to 9 are diagrams to illustrate an operation of a light-emitting element in which a diode type bank is disposed according to an embodiment of the present disclosure.

FIGS. 10 to 12 show a head-mounted display apparatus including a display device according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Hereinafter, a display device according to some embodiments will be described.

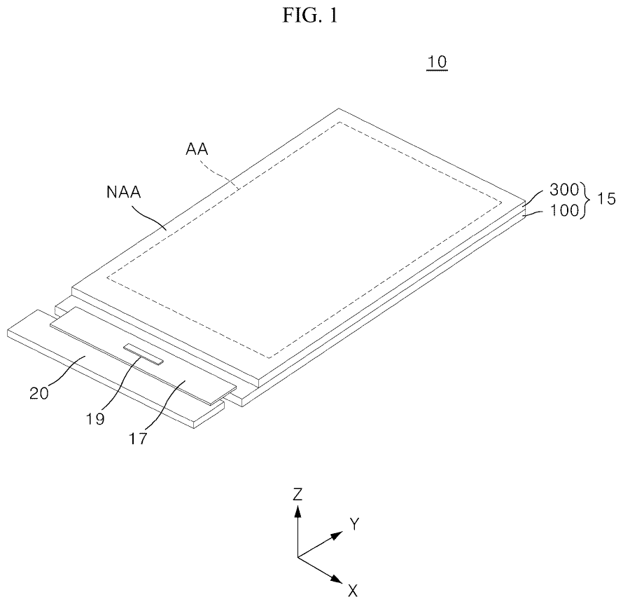

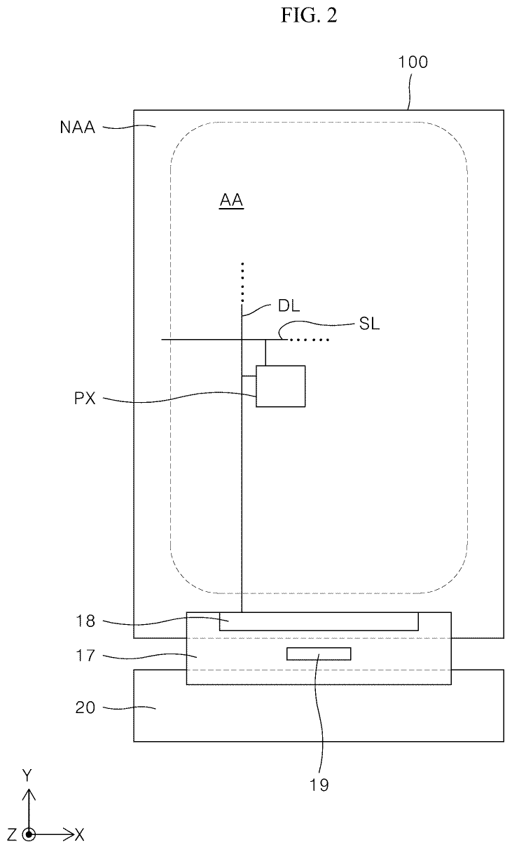

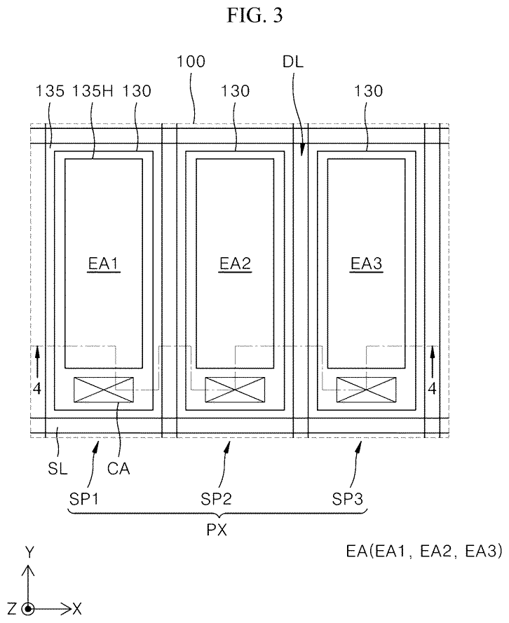

FIG. 1 is a schematic perspective view of a display device according to an embodiment of the present disclosure. FIG. 2 is a plan view schematically showing a portion of a display device according to an embodiment of the present disclosure. FIG. 3 is an enlarged plan view of an area 3 in FIG. 2.

Referring to FIGS. 1 to 3, a display device 10 according to an embodiment of the present disclosure may include a display panel 15 having a display area AA and a non-display area NAA located outside the display area AA according to an embodiment of the present disclosure.

The display area AA may be an area where an image is displayed and the non-display area NAA may be an area where the image is not displayed. The non-display area NAA may include an upper edge area, a lower edge area, a left edge area, and a right edge area of the display panel 15. The non-display area NAA may be located outside of the display area AA. However, embodiments of the present disclosure are not limited thereto. For example, a remaining area excluding a light-emissive area where light is emitted to the outside on the display area AA may be included as the non-display area NAA.

A flexible circuit board 17 and a printed circuit board 20 may be disposed on an edge of at least one side of the non-display area NAA. An integrated circuit chip 19 may be disposed on the flexible circuit board 17. One side of the flexible circuit board 17 may be coupled to a first substrate 100 and the other side thereof may be coupled to the printed circuit board 20 to provide power and signals for driving a light-emitting element supplied from the printed circuit board 20 to the display area AA of the first substrate 100. For example, the signals for driving the light-emitting element may include a high-potential voltage, a low-potential voltage, a scan signal, a data signal, a touch detection signal, or the like.

The printed circuit board 20 may supply the signals to the integrated circuit chip 19 disposed on the flexible circuit board 17. Various components to supply the various signals to the integrated circuit chip 19 may be disposed on the printed circuit board 20. It is shown in FIG. 1 that there are a single flexible circuit board 17 and a single printed circuit board 20, but the present disclosure is not limited thereto. For example, a plurality of flexible circuit boards 17 and a plurality of printed circuit boards 20 may be disposed on the edge at one side of the first substrate 100.

A pad 18 may be located on the non-display area NAA of the first substrate 100 and may include a plurality of electrode pads. The flexible circuit board 17 equipped with the integrated circuit chip 19 may be attached onto the pad 18. In one example, the flexible circuit board 17 and the pad 18 may be attached to each other using an anisotropic conductive film. The electrode pads included in the pad 18 may include a plurality of power supply pads, a plurality of data supply pads, and a control signal supply pad, a plurality of common power supply pads, or the like for transmitting the power and the various signals to drive the light-emitting element supplied from the printed circuit board 20 to the display area AA.

The display panel 15 includes the first substrate 100 and a second substrate 300. The first substrate 100 may include transparent plastic or glass. The second substrate 300 may include a transparent plastic film, a glass substrate, or an encapsulation film. The first substrate 100 or the second substrate 300 may have a square shape or may have a square shape with each corner having a rounded shape when viewed from a plane. The second substrate 300 may be referred to as a cover window, a window cover, or a cover glass that covers the first substrate 100.

A plurality of pixels PX may be arranged on the display area AA of the first substrate 100. The image may be displayed in the display area AA via the plurality of pixels PX. In the non-display area NAA, several drivers to drive the plurality of pixels PX arranged on the display area AA may be disposed. For example, the drivers may include a gate driver, a data driver, a touch driver, and a timing controller. However, embodiments of the present disclosure are not limited thereto.

Referring to FIG. 3 along with FIG. 2, a plurality of data lines DL and a plurality of scan lines SL may be disposed on the display area AA. Each of the plurality of data lines DL may be disposed to intersect each of the plurality of scan lines SL. The pixel PX may be defined by one data line DL and one scan line SL that intersect each other. The pixel PX may include a plurality of sub-pixels SP1, SP2, and SP3 emitting light of different colors. Each of the plurality of sub-pixels SP1, SP2, and SP3 may be electrically connected to the scan line SL and the data line DL.

The plurality of sub-pixels SP1, SP2, and SP3 may be arranged on the display area AA of the first substrate 100, and may be arranged in a matrix along a first direction and a second direction intersecting the first direction of the first substrate 100. The first direction may be an X-axis direction or a horizontal direction, and the second direction may be a Y-axis direction or a vertical direction. However, the present disclosure may not be limited thereto, and arrangement order and direction of the sub-pixels SP1, SP2, and SP3 may be changed in various ways.

The sub-pixels SP1, SP2, and SP3 may include the light-emitting elements and may emit red, green, or blue light, respectively. A plurality of light-emissive areas EA may be located correspondingly by the light-emitting elements disposed in the sub-pixels SP1, SP2, and SP3, respectively. The plurality of light-emissive areas EA may include a first light-emissive area EA1 located in the first sub-pixel SP1, a second light-emissive area EA2 located in the second sub-pixel SP2, and a third light-emissive area EA3 located in the third sub-pixel SP3.

A plurality of first electrodes 130 are disposed corresponding to the plurality of sub-pixels SP1, SP2, and SP3, respectively. The plurality of first electrodes 130 may be disposed to be spaced apart from each other.

Each of the plurality of light-emissive areas EA1, EA2, and EA3 may be defined by a bank hole 135H defined in a diode type bank, 135. Respective portions of the plurality of first electrodes 130 that are not covered by the diode type banks 135 and are exposed by the bank holes 135H may be the light-emissive areas EA1, EA2, and EA3. A remaining area excluding the light-emissive areas EA, EA2, and EA3 may be a non-light-emissive area. The diode type bank 135 may be disposed overlapping the non-light-emissive area.

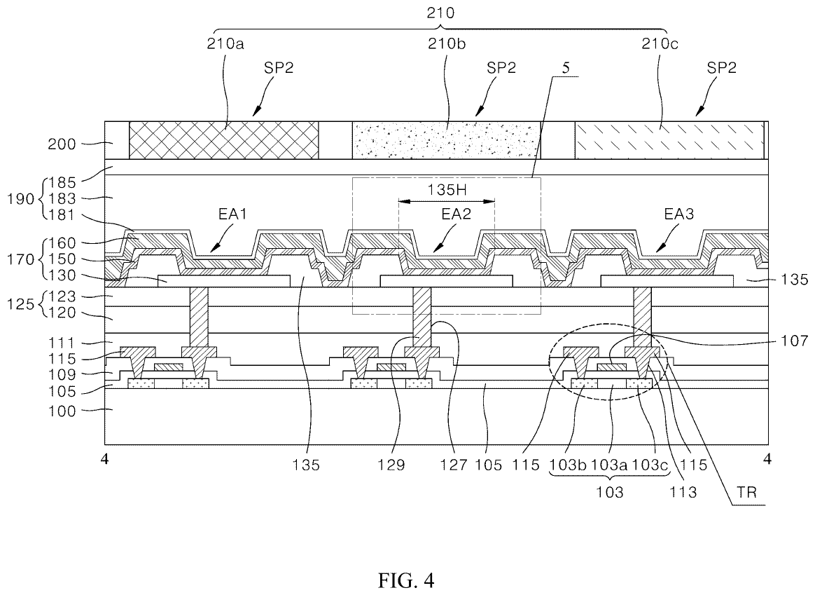

The first electrode 130 disposed on each of the plurality of sub-pixel SP1, SP2, and SP3 may be connected to at least one transistor disposed on the first substrate 100 via each contact area CA. The contact area CA may include a contact electrode that electrically connects the first electrode 130 to the transistor. This will be described with reference to FIG. 4.

The display device according to an embodiment of the present disclosure may be of one of a top emission scheme and a bottom emission scheme, depending on a direction in which light emitted from a light-emitting layer is emitted. Hereinafter, the top emission scheme will be described as an example.

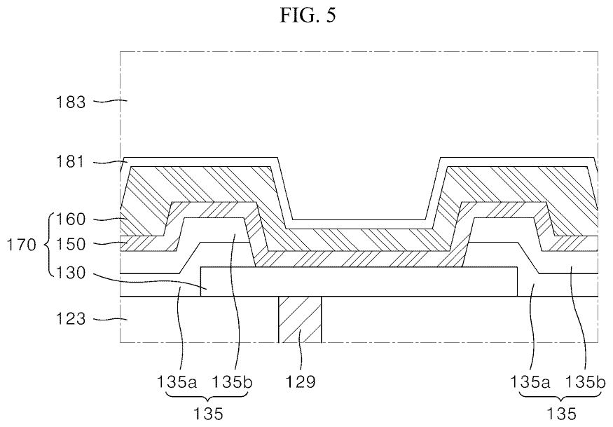

FIG. 4 is a cross-sectional view along a line 4-4 in FIG. 3 according to an embodiment of the present disclosure. Further, FIG. 5 is an enlarged cross-sectional view of an area 5 in FIG. 4 according to an embodiment of the present disclosure.

Referring to FIGS. 4 and 5, a transistor TR may be disposed on the first substrate 100. The first substrate 100 may include a silicon wafer. In one embodiment, the first substrate 100 may include glass or plastic.

The first substrate 100 may have a driver circuit including various signal lines, transistors, capacitors, and the like for each of the sub-pixels SP1, SP2, and SP3. The signal lines may include a gate wiring, a data wiring, a power wiring, and a reference wiring, and the transistors TR may include a switching transistor and a driving transistor. For example, the switching transistor and the driving transistor may be formed on the first substrate 100 using a complementary metal oxide semiconductor (CMOS) process.

The switching transistor switches in response to a gate signal supplied to the gate wiring, supplies a data voltage supplied from the data wiring to the driving transistor, and selects the sub-pixel SP1, SP2, and SP3. The driving transistor drives the light-emitting element by supplying power to the first electrode of the sub-pixel SP1, SP2, and SP3 selected by the switching transistor.

The capacitor may serve to maintain the data voltage supplied to the driving transistor for one frame, and electrodes of the capacitor may be electrically connected to the driving transistor.

The transistor TR may include an active semiconductor layer 103, a gate insulating layer 105, a gate electrode 107, and a source/drain electrode 115. The gate insulating layer 105 may be disposed between the active semiconductor layer 103 and the gate electrode 107. An insulating layer that reduces or prevents penetration of moisture or impurities may be further included between the first substrate 100 and the active semiconductor layer 103.

The active semiconductor layer 103 may be made of an oxide semiconductor or silicon-based semiconductor material. For example, the active semiconductor layer 103 may include a transparent oxide semiconductor material such as indium-gallium-zinc-oxide (IGZO) or indium-zinc-oxide (IZO). Furthermore, the active semiconductor layer 103 may include a polysilicon semiconductor material.

The active semiconductor layer 103 may include a channel area 103a, a source area 103b, and a drain area 103c. The gate insulating layer 105 may be composed of a single layer or a plurality of layers of silicon oxide (SiOx) or silicon nitride (SiNx).

The gate electrode 107 may be disposed on the gate insulating layer 105. An area of the active semiconductor layer 103 that overlaps the gate electrode 107 in a vertical direction may be the channel area 103a. The source area 103b and the drain area 103c may be located on both sides of the channel area 103a.

An interlayer insulating layer 109 and a passivation layer 111 may be sequentially disposed on the gate electrode 107.

The interlayer insulating layer 109 and a source/drain electrode 115 that fills a contact hole 113 extending through the gate insulating layer 105 may be disposed sequentially on the gate electrode 107. The source/drain electrodes 115 may be connected to the source area 103b and the drain area 103c of the active semiconductor layer 103, respectively.

A planarization layer 125 may be disposed on the passivation layer 111 and the source/drain electrode 115. The planarization layer 125 may include a first planarization layer 120 and a second planarization layer 123. The planarization layer 125 serves to planarize a step generated by a lower circuit element including the transistor (such as a driving transistor) TR.

The planarization layer 125 may include a pixel contact hole 127 extending through the first planarization layer 120 and the second planarization layer 123 while exposing a portion of a surface of the source/drain electrode 115 of the transistor TR. The pixel contact electrode 129 may fill the pixel contact hole 127 while one surface thereof is in contact with the source/drain electrode 115.

The first electrode 130 may be disposed on the second planarization layer 123. The first electrode 130 may include transparent conductive oxide (TCO) such as indium-tin-oxide (ITO) or indium-zinc-oxide (IZO). Alternatively, the first electrode 130 may have a single-layer or multi-layer structure including a reflective metal film made of silver (Ag), aluminum (Al), gold (Au), nickel (Ni), chromium (Cr), and compounds thereof. The first electrode 130 may also be referred to as an anode electrode or a pixel electrode.

A bank that separates the neighboring sub-pixels SP1, SP2, and SP3 from each other may be disposed on the second planarization layer 123. The bank according to the present disclosure may be the diode type bank 135. The diode type bank 135 may be formed to cover an edge of the first electrode 130. In the diode type bank 135, the light-emissive areas EA1, EA2, and EA3 may be implemented via the bank hole 135H, which is an opening.

Referring to FIG. 5, the diode type bank 135 may include a structure in which a first semiconductor layer 135a and a second semiconductor layer 135b are joined together. The first semiconductor layer 135a and the second semiconductor layer 135b of the diode type bank 135 may include amorphous silicon. Polycrystalline silicon or single crystal silicon has atoms arranged regularly inside. In comparison, the amorphous silicon has atoms arranged irregularly inside, and thus has a light absorption coefficient greater than that of the single crystalline silicon or the polycrystalline silicon. Accordingly, the amorphous silicon may have opaque characteristics. The diode type bank 135 according to the present disclosure may have a density lower than that of the polycrystalline silicon or the single crystalline silicon. The diode type bank 135 with the low density may have a light transmittance lower than 5% because of an increased internal light scattering effect. Therefore, the diode type bank 135 may prevent light of the different colors from being mixed with each other and output between the adjacent sub-pixels.

The first semiconductor layer 135a of the diode type bank 135 may include amorphous silicon doped with a first conductivity type impurity, and the second semiconductor layer 135b may include amorphous silicon doped with a second conductivity type impurity. The first conductivity type impurity and the second conductivity type impurity may be impurities of different conductivity types. For example, the first conductivity type impurity may include n-type impurities such as phosphorus (P), arsenic (AS), or antimony (Sb). The second conductivity type impurity may include p-type impurities such as boron (B), aluminum (Al), gallium (Ga), or indium (In).

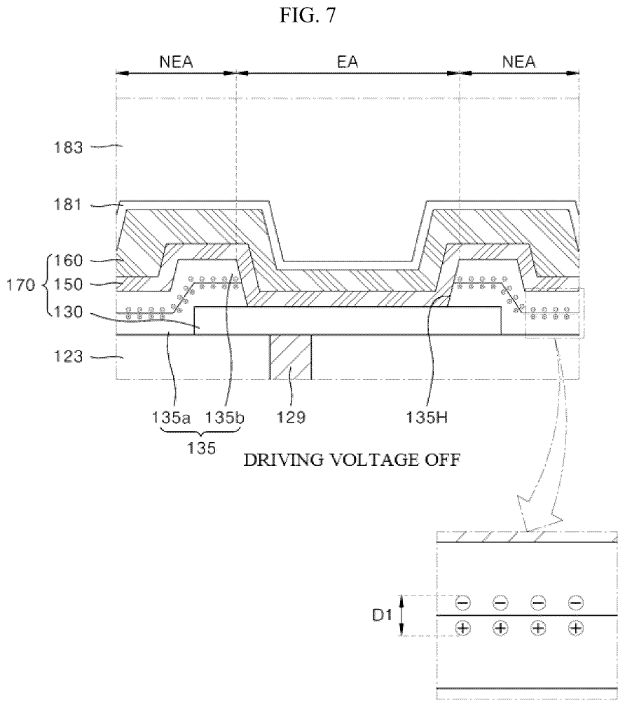

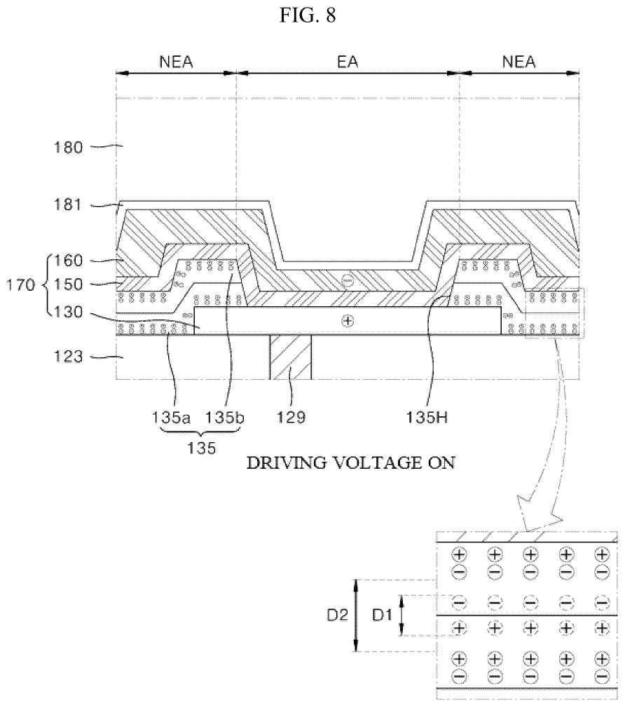

As the diode type bank 135 has the structure in which the first semiconductor layer 135a and the second semiconductor layer 135b are joined together, a depletion area in which no current flows may be implemented at an interface where the first semiconductor layer 135a and the second semiconductor layer 135b are joined together. Because no current flows in the depletion area, the depletion area may act like an insulating material. This will be described later via FIGS. 7 and 8.

An organic light-emitting layer 150 may be disposed on the first electrode 130. In one example, the organic light-emitting layer 150 may include an organic material that emits white light.

The organic light-emitting layer 150 may include a stack structure including a hole transport layer (HTL), an emission material layer (EML) and an electron transport layer (ETL), a hole blocking layer (HBL), a hole injecting layer (HIL), and an electron blocking layer (EBL) and an electron injecting layer (EIL). In one example, the organic light-emitting layer 150 may have a multi-layer stack structure in which at least two layers of the stack structure are stacked. However, embodiments of the present disclosure are not limited thereto.

The organic light-emitting layer 150 may be disposed on a front surface of the first substrate 100. Accordingly, the organic light-emitting layer 150 may have a shape that extends with continuity along a shape of the diode type bank 135.

A second electrode 160 may be disposed on the organic light-emitting layer 150. The second electrode 160 may be a common layer commonly formed on the plurality of sub-pixels SP1, SP2, and SP3. The second electrode 160 may be referred to as a cathode electrode or a common electrode. The second electrode 160 may include a transmissive or semi-transmissive material. When the second electrode 160 is transmissive, the second electrode 160 may include transparent conductive oxide (TCO). For example, the second electrode 160 may include indium-tin-oxide (ITO) or indium-zinc-oxide (IZO). When the second electrode 160 is semi-transmissive, the second electrode 160 may include a metal material such as magnesium (Mg), silver (Ag), or an alloy of magnesium (Mg) and silver (Ag).

A light-emitting element 170 may be composed of the first electrode 130, the organic light-emitting layer 150, and the second electrode 160. The display device according to an embodiment of the present disclosure may include an organic light-emitting element with ultra-high resolution. The organic light-emitting element with the ultra-high resolution may be an organic light-emitting element formed on the first substrate 100 including a silicon wafer (an organic light emitting diode on silicon; OLEDos).

The first electrode 130 may supply holes to the organic light-emitting layer 150, and the second electrode 160 may supply electrons to the organic light-emitting layer 150. When voltage is applied based on the signal transmitted from the drivers, light generated from recombination of the holes supplied from the first electrode 130 to the organic light-emitting layer 150 and the electrons supplied from the second electrode 160 to the organic light-emitting layer 150 may be emitted. A light extraction efficiency of light generated from the organic light-emitting layer 150 may be increased by a micro-cavity phenomenon. For example, light generated from the organic light-emitting layer 150 is reflected between the first electrode 130 and the second electrode 160 and the micro-cavity phenomenon via constructive interference occurs, thereby improving the light extraction efficiency.

An encapsulation portion 190 may be disposed on the second electrode 160. The encapsulation portion 190 may prevent the moisture or oxygen from penetrating into the transistor TR and the light-emitting element 170 located below. The encapsulation portion 190 may be a multi-layer structure of an inorganic insulating layer and an organic insulating layer. For example, the encapsulation portion 190 may include a first encapsulation layer 181, a second encapsulation layer 183, and a third encapsulation layer 185. Each of the first encapsulation layer 181 and the third encapsulation layer 185 may include an inorganic insulating material. For example, the inorganic insulating material may be selected from silicon nitride, aluminum nitride, zirconium nitride, titanium nitride, hafnium nitride, tantalum nitride, silicon oxide, aluminum oxide, titanium oxide, or the like. The second encapsulation layer 183 may planarize steps generated by the light-emitting element 170 and the diode type bank 135 and prevent the foreign substances from penetrating into the light-emitting element 170. The second encapsulation layer 183 may include an organic insulating material.

A color filter 210 may be disposed on the third encapsulation layer 185. The color filter 210 may be disposed to correspond to each of the plurality of sub-pixels SP1, SP2, and SP3. The color filter 210 may include a first color filter 210a, a second color filter 210b, and a third color filter 210c. The first color filter 210a of a first color may be located corresponding to the first sub-pixel SP1, the second color filter 210b of a second color may be located corresponding to the second sub-pixel SP2, and the third color filter 210c of a third color may be located corresponding to the third sub-pixel SP3. The first color may be red, the second color may be green, and the third color may be blue. However, embodiments of the present disclosure are not limited thereto.

A black matrix 200 may be disposed at a border between the neighboring color filters 210a, 210b, and 210c. However, embodiments of the present disclosure are not limited thereto.

On the color filter 210, the second substrate 300 in FIG. 1 may be disposed at a location facing the first substrate 100 and may be bonded to the first substrate 100. The first substrate 100 and the second substrate 300 may be bonded together using an adhesive member (not shown) such as transparent adhesive resin.

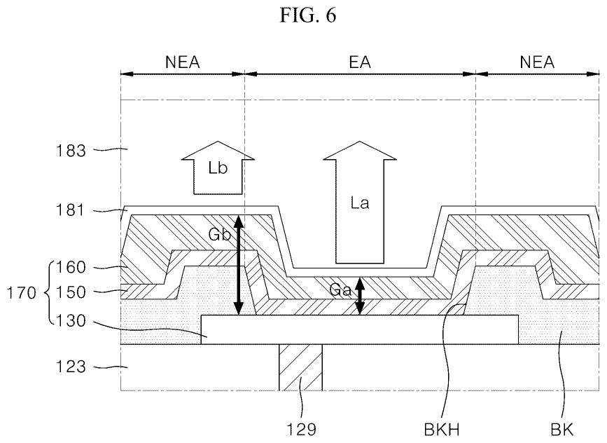

FIG. 6 is an enlarged cross-sectional view of one sub-pixel according to Comparative Example. For convenience of description, components that are redundant with those in FIG. 5 are indicated with the same reference numerals in FIG. 6.

Referring to FIG. 6, in Comparative Example, a bank BK containing an insulating material may be disposed at an edge of the first electrode 130. The bank BK, which includes the insulating material, may prevent defects such as no light emission or reduced luminance caused by electrical short circuit resulted from a thin deposition of the organic light-emitting layer 150 at the edge of the first electrode 130. For example, the insulating material constituting the bank BK may be an organic insulating material including an acrylic material or black resin. However, in the display device to realize the ultra-high resolution, the organic insulating material is lack of resolution, making it difficult to accurately pattern the bank BK that separates the sub-pixels from each other. Accordingly, an inorganic insulating material is applied to the bank BK in the display device to realize the ultra-high resolution. For example, the inorganic insulating material may include transparent silicon nitride (SiNx) or silicon oxide (SiOx).

One sub-pixel includes a light-emissive area EA defined by a bank hole BKH defined in the bank BK and a non-light-emissive area NEA where light is blocked by the bank BK. The light-emissive area EA may be an area where light generated by the light-emitting element 170 of the display device is emitted to the outside. The non-light-emissive area NEA may be an area where light is not emitted to the outside. The non-light-emissive area NEA may extend from the light-emissive area EA and include the edge of the first electrode 130 covered by the bank BK.

Light emitted to the outside from the light-emissive area EA may be referred to as first emitted light La. In the respective plurality of sub-pixels, the first emitted light La of different colors may be emitted to the outside. In the non-light-emissive area NEA, as it is covered by the bank BK, light should not be emitted to the outside. However, according to Comparative Example in which the bank BK is made of a transparent insulating material, second emitted light Lb may be emitted to the outside in the non-light-emissive area NEA.

For example, when leakage current occurs at the edge of the first electrode 130 in the non-light-emissive area NEA, because the bank BK is made of a transparent inorganic insulating material, light that has passed through the bank BK may be reflected by the second electrode 160 to generate reflected light and this reflected light may become the second emitted light Lb that is emitted to the outside.

The non-light-emissive area NEA has a different cell gap from the light-emissive area EA because the arrangement of the bank BK. The cell gap may be a distance between the first electrode 130 and the second electrode 160. For example, the light-emissive area EA may have a first cell gap Ga of a first distance between the first electrode 130 and the second electrode 160. As the bank BK is disposed between the first electrode 130 and the second electrode 160, the non-light-emissive area NEA may have a second cell gap Gb with a second distance that is relatively greater than that of the light-emissive area EA.

As the light-emissive area EA and the non-light-emissive area NEA have the first and second cell gaps Ga and Gb of the different distances, respectively, the first emitted light La and the second emitted light Lb having different wavelengths are emitted to the outside. Because the second emitted light Lb is emitted through the bank BK made of the transparent material, the second emitted light Lb may have an intensity that may cause an interference effect on the color of the first emitted light La.

As the two first and second emitted light La and Lb with different wavelengths are emitted from one sub-pixel, color coordinates of a color to be realized may be deviated, which may cause color gamut deterioration. The color gamut, as a range of colors that may be rendered in the display device, may be referred to as a color expression or a color area.

For example, a sub-pixel that emits light of the first color should emit light having a peak wavelength corresponding to the first color in the light-emissive area EA. The peak wavelength may refer to a wavelength at which an intensity is maximum within a wavelength area. However, when the two first and second emitted light La and Lb with the different wavelengths are emitted from one sub-pixel, intensities of not only the peak wavelength but also a sub-peak wavelength increase to cause interference in realizing the first color, so that the color gamut may deteriorate.

In terms of such problem, the display device according to an embodiment of the present disclosure may prevent the color gamut from deteriorating by implementing the bank as the diode type bank 135. Hereinafter, this will be described with reference to FIGS. 7 and 8.

FIGS. 7 to 9 are diagrams to illustrate an operation of a light-emitting element in which a diode type bank is disposed according to an embodiment of the present disclosure. For convenience of description, FIGS. 7 to 9 will be described as an enlarged portion of an area 5 in FIG. 4. In particular, FIG. 7 shows a state in which no driving voltage is applied to the light-emitting element in which the diode type bank is disposed. FIG. 8 shows a state in which the driving voltage is applied to the light-emitting element in which the diode type bank is disposed. Further, FIG. 8 shows emitted light of the light-emitting element to which the driving voltage is applied.

Referring to FIGS. 7 to 9, the diode type bank 135 according to an embodiment of the present disclosure may be a structure in which the first semiconductor layer 135a and the second semiconductor layer 135b are joined together. In the diode type bank 135, the first semiconductor layer 135a may be located at a lower side and the second semiconductor layer 135b may be disposed on the first semiconductor layer 135a. The first semiconductor layer 135a may include the amorphous silicon containing the first conductivity type impurity, and the second semiconductor layer 135b may include the amorphous silicon containing the second conductivity type impurity. The first conductivity type impurity may include the n-type impurity, and the second conductivity type impurity may include the p-type impurity.

As shown in FIG. 7, when the driving voltage for driving the light-emitting element 170 is not applied, a first depletion area D1 with a first width may be created in a boundary area where the first semiconductor layer 135a and the second semiconductor layer 135b are joined together in the diode type bank 135. In the first depletion area D1, ions with a (+) charge are disposed in the first semiconductor layer 135a and ions with a (−) charge are disposed in the second semiconductor layer 135b, creating an area in which no current flows. Further, the ions with the (−) charge are included as majority carriers in the first semiconductor layer 135a excluding the first depletion area D1, and the ions with the (+) charge are included as the majority carriers in the second semiconductor layer 135b excluding the first depletion area D1.

As shown in FIG. 8, when the driving voltage to drive the light-emitting element 170 is applied, the first electrode 130 may supply holes to the organic light-emitting layer 150, and the second electrode 160 may supply electrons to the organic light-emitting layer 150. For example, a positive (+) voltage may be applied to the first electrode 130, and a negative (−) voltage may be applied to the second electrode 160.

When the driving voltage to drive the light-emitting element 170 is applied, a reverse voltage may be applied to the diode-type bank 135 disposed to overlap and cover the edge of the first electrode 130. The state in which the reverse voltage is applied to the diode type bank 135 may be a state of applying the (+) voltage to the first semiconductor layer 135a containing the n-type impurity and applying the (−) voltage to the second semiconductor layer 135b containing the p-type impurity.

When the reverse voltage is applied to the diode type bank 135, the ions with the (−) charge, which are the majority carriers contained in the first semiconductor layer 135a, may be attracted to the (+) voltage applied to the first electrode 130, and the ions with the (+) charge, which are the majority carriers contained in the second semiconductor layer 135b, may be attracted to the (−) voltage applied to the second electrode 160. Then, a second depletion area D2 with a second width that is greater than the first width of the first depletion area D1 may be created. As a result, an area where current does not flow and that acts like an insulating material increases, thus allowing the diode type bank 135 to perform the function of the insulating film. In other words, the second depletion area D2 may have insulating properties, so that the diode type bank 135 may act as the insulating material.

Furthermore, the diode type bank 135 includes the low-density amorphous silicon. As the amorphous silicon has the structure in which the atoms are arranged irregularly inside, the amorphous silicon has the lowest electron carrier mobility compared to the single crystal silicon or the polycrystalline silicon, so that the function thereof as the insulating film may be further improved when the reverse voltage is applied.

As the diode type bank 135 includes the low-density amorphous silicon, the diode type bank 135 may have a light transmittance lower than 5%. Accordingly, light emitted from the light-emitting element 170 may be prevented or reduced from passing through the diode type bank 135 and being emitted to the outside.

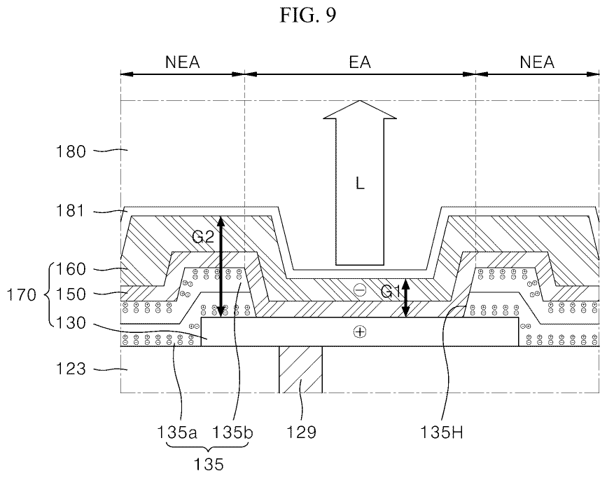

Specifically, referring to FIG. 9, the diode type bank 135 is disposed in the non-light-emissive area NEA. The diode type bank 135 may include the low-density amorphous silicon. As the amorphous silicon has the structure in which the atoms are arranged irregularly inside, an effect of light emitted from the light-emitting element 170 being scattered inside the diode type bank 135 increases, which may reduce the transmittance. Accordingly, while first emitted light L having a peak wavelength of a first color is emitted to the outside in the light-emissive area EA, light may be prevented or reduced from being emitted to the outside by the diode type bank 135 in the non-light-emissive area NEA.

For example, the non-light-emissive area NEA and the light-emissive area EA have cell gaps G1 and G2 of different distances. The light-emissive area EA may have a first cell gap G1 of a first distance between the first electrode 130 and the second electrode 160, and the non-light-emissive area NEA may have a second cell gap G2 relatively greater than that of the light-emissive area EA by the diode type bank 135.

The emitted light L of the first color may be emitted from the light-emissive area EA having the first cell gap G1. In the non-light-emissive area NEA having the second cell gap G2, reflected light with a wavelength different from that of the first color may occur. However, the reflected light may be prevented from being emitted to the outside by being scattered and absorbed inside the diode type bank 135 or may be emitted to the outside with a transmittance lower than 5%. Furthermore, the reflected light emitted to the outside with the transmittance lower than 5% has an intensity significantly lower than an intensity that may interfere with rendering the first color, thereby preventing the effect of interference from occurring in rendering the first color.

Accordingly, one sub-pixel may emit the emitted light L having the peak wavelength corresponding to the first color to the outside via the micro-cavity phenomenon, thereby improving the color gamut.

According to an embodiment of the present disclosure, the color gamut of the emitted light that is emitted from the light-emitting element to the outside may be improved as the diode type bank that may achieve excellent light-blocking characteristics is included. As the color gamut improves, the light-emitting element may be driven with low power, thereby reducing production energy.

According to an embodiment of the present disclosure, as the diode type bank is included, problems that occur when using the bank containing the organic or inorganic insulating material may be prevented.

According to an embodiment of the present disclosure, as the diode type bank is included, the color gamut deterioration of the display device caused by the emitted light emitted from the non-light-emissive area may be prevented.

Note that, although the present disclosure is described herein mainly in conjunction with an example in which the light-emitting element included in the display device is an organic light-emitting element, the present disclosure is not limited thereto, and a suitable light-emitting element may be used by a person skilled in the art according to actual needs. In addition, although the specific structure of the diode type bank is described above in conjunction with an example shown in the accompanying drawings, the structure of the diode type bank is not limited to the above example, and a person skilled in the art may select a suitable structure of the diode type bank according to actual needs.

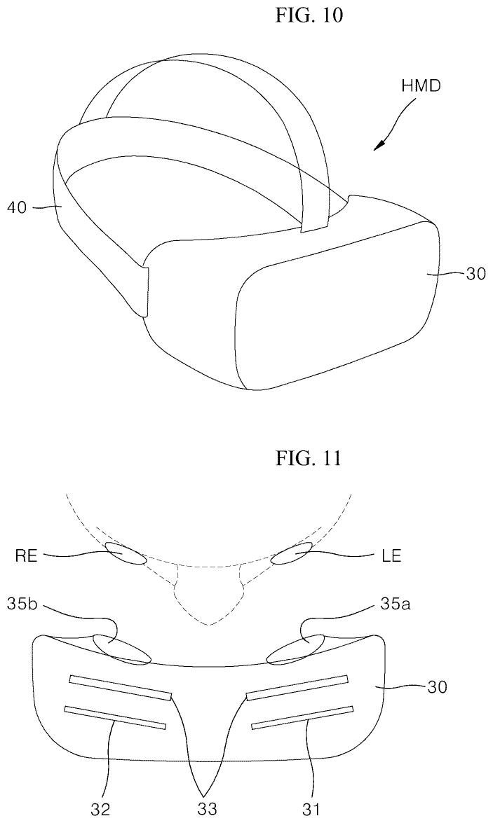

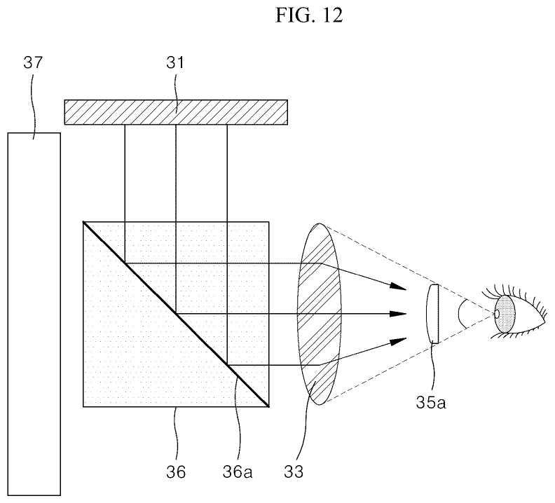

FIGS. 10 to 12 are diagrams of head-mounted display apparatus including a display device according to an embodiment of the present disclosure. Specifically, FIG. 10 is a schematic perspective view of a head-mounted display apparatus including a display device according to an embodiment of the present disclosure, and FIG. 11 is a top view showing a head-mounted display apparatus implementing virtual reality. FIG. 12 is a side view showing a head-mounted display apparatus that implements augmented reality.

Referring to FIG. 10, the head-mounted display apparatus including a display device according to an embodiment of the present disclosure may include a case 30 and a head mounting band 40.

The case 30 may receive therein components such as a display device, a lens array, an eyepiece, a sound device, an accelerometer, and a position sensor, etc. The head mounting band 40 is fixed to the case 30. The head mounting band 40 is illustrated as being formed to surround an upper surface and both opposing side surfaces of the user's head. However, embodiments of the present disclosure are not limited thereto. The head mounting band 40 is used to secure the head-mounted display apparatus to the user's head. In another example, the head mounting band 40 may be embodied as an eyeglass frame or a helmet-shaped structure that entirely surrounds the user's head.

The head-mounted display apparatus may include a display device according to an embodiment of the present disclosure as described in FIG. 4 and may provide an image implementing virtual reality (VR) or an image implementing augmented reality (AR) to the user.

Referring to FIG. 11, the head-mounted display apparatus that implements virtual reality may include a display device 31 for a left-eye, a display device 32 for a right-eye, a lens array 33, and a left-eye eyepiece 35a and a right-eye eyepiece 35b. The display device 31 for a left-eye and the display device 32 for right-eye, the lens array 33, and the left-eye eyepiece 35a and the right-eye eyepiece 35b may be received in the case 30.

The display device 31 for a left-eye and the display device 32 for a right-eye may display the same image. When the display device 31 for a left-eye and the display device 32 for a right-eye display the same image, the user may view the 2D image through the head-mounted display apparatus. Alternatively, the display device 31 for a left-eye may display an image for a left-eye, and the display device 32 for a right-eye may display an image for a right-eye that is different from the image for a left-eye. In this case, the user may view a three-dimensional image through the head-mounted display apparatus. Each of the display device 31 for a left-eye and the display device 32 for a right-eye may include the display device according to FIG. 4 as described above.

One of the lens arrays 33 may be spaced apart from each of the left-eye eyepiece 35a and the display device for a left-eye 31, and may be disposed between the left-eye eyepiece 35a and the display device for a left-eye 31. That is, one of the lens arrays 33 may be located in front of the left-eye eyepiece 35a and in rear of the display device for a left-eye 31. Furthermore, the other of the lens array 33 may be spaced away from each of the right-eye eyepiece 35b and the display device for a right-eye 32, and may be disposed between the right-eye eyepiece 35b and the display device for a right-eye 32. That is, the other of the lens array 33 may be located in front of the right-eye eyepiece 35b and in rear of the display device for a right-eye 32.

The lens array 33 may include, but is not limited to, a micro lens array. In one example, the lens array 33 may include a pin hole array. The image displayed from the display device for a left-eye 31 or the display device for a right-eye 32 may be visible to the user in an enlarged manner due to the lens array 33. The user's left-eye LE may be located in rear of the left-eye eyepiece 35a, and the user's right-eye RE may be located in rear of the right-eye eyepiece 35b.

Referring to FIG. 12, the head-mounted display apparatus that implements augmented reality includes the display device for a left-eye 31, the lens array 33, the left-eye eyepiece 35a, a transmissive and reflective portion 36, and a transmissive window 37. For convenience of illustration, FIG. 12 shows only a configuration related to the left-eye, and a configuration related to the right-eye is the same or similar to the configuration related to the left-eye.

The display device for a left-eye 31, the lens array 33, the left-eye eyepiece 35a, the transmissive and reflective portion 36, and the transmissive window 37 are housed in case 30 (see FIG. 10). The display device for a left-eye 31 may be disposed on one side of the transmissive and reflective portion 36, for example, on an upper side thereof so that the display device for a left-eye 31 does not block the transmissive window 37. Accordingly, the display device for a left-eye 31 may provide an image to the transmissive and reflective portion 36 without blocking an external background visible through the transmissive window 37.

The display device 31 for a left-eye may include the display device according to one embodiment of the present disclosure as shown in FIG. 4. The lens array 33 may be provided between the left-eye eyepiece 35a and the transmissive and reflective portion 36. The user's left-eye may be located in rear of the left-eye eyepiece 35a.

The transmissive and reflective portion 36 is disposed between the lens array 33 and the transmissive window 37. The transmissive and reflective portion 36 may include a transmissive and reflective surface 36a that transmits a portion of light therethrough and reflects the other portion of light therefrom. The transmissive and reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The transmissive and reflective surface 36a may be formed to allow the image displayed from the display device for a left-eye 31 to be directed to the lens array 33.

Therefore, the user may view both the external background visible through the transmissive window 37 and the image displayed from the display device for a left-eye 31. In other words, the user may view both the real background and the virtual image as one image in an overlapping manner. Thus, the augmented reality may be implemented.

A display device according to an embodiment of the present disclosure includes a substrate including a light-emissive area and a non-light-emissive area, a diode type bank located on the non-light-emissive area and separating a plurality of sub-pixels from each other, a light-emitting element disposed in each of the plurality of sub-pixels, and an encapsulation portion disposed on the light-emitting element.

In the display device according to some embodiments of the present disclosure, the diode type bank may include an opaque semiconductor material.

In the display device according to some embodiments of the present disclosure, the diode type bank may include a first semiconductor layer and a second semiconductor layer disposed on the first semiconductor layer.

In the display device according to some embodiments of the present disclosure, the first semiconductor layer may include amorphous silicon doped with a first conductivity type impurity, the second semiconductor layer may include amorphous silicon doped with a second conductivity type impurity, and the first conductivity type impurity and the second conductivity type impurity may be of different conductivity types.

In the display device according to some embodiments of the present disclosure, the first conductivity type impurity may include n-type impurities including phosphorus (P), arsenic (AS), or antimony (Sb), and the second conductivity type impurity may include p-type impurities including boron (B), aluminum (Al), gallium (Ga), or indium (In).

In the display device according to some embodiments of the present disclosure, each of the first semiconductor layer and the second semiconductor layer may have a lower density than polycrystalline silicon or single crystalline silicon.

In the display device according to some embodiments of the present disclosure, the first semiconductor layer and the second semiconductor layer may have a light transmittance lower than 5%.

In the display device according to some embodiments of the present disclosure, the light-emitting element may include a first electrode overlapping the light-emissive area and having an edge covered by the diode type bank, an organic light-emitting layer disposed on the first electrode, and a second electrode disposed on the organic light-emitting layer.

In the display device according to some embodiments of the present disclosure, the diode type bank may include a first semiconductor layer having a portion overlapping an edge of the first electrode, wherein the first semiconductor layer is doped with a first conductivity type impurity, a second semiconductor layer disposed on the first semiconductor layer and doped with a second conductivity type impurity different from the first conductivity type impurity, and a first depletion area of a first width disposed in a boundary area between the first semiconductor layer and the second semiconductor layer.

In the display device according to some embodiments of the present disclosure, the first conductivity type impurity may include n-type impurities, and the second conductivity type impurity may include p-type impurities.

In the display device according to some embodiments of the present disclosure, the diode type bank may be disposed between the first electrode receiving a positive (+) voltage and the second electrode receiving a negative (−) voltage, wherein the diode type bank includes a second depletion area between the first semiconductor layer and the second semiconductor layer, the second depletion region has a second width greater than first width of the first depletion region, and wherein no current flows in the second depletion area.

A head-mounted display apparatus according to an embodiment of the present disclosure includes a display device, a case for accommodating the display device therein, and a lens array that is disposed at one side of the case and displays an image output from the display device, and the display device includes a substrate including a light-emissive area and a non-light-emissive area, a diode type bank located on the non-light-emissive area and separating a plurality of sub-pixels from each other, a light-emitting element disposed in each of the plurality of sub-pixels, and an encapsulation portion disposed on the light-emitting element.

In the head-mounted display apparatus according to some embodiments of the present disclosure, the diode type bank may include a first semiconductor layer and a second semiconductor layer disposed on the first semiconductor layer.

In the head-mounted display apparatus according to some embodiments of the present disclosure, the first semiconductor layer may include amorphous silicon doped with a first conductivity type impurity, the second semiconductor layer may include amorphous silicon doped with a second conductivity type impurity, and the first conductivity type impurity and the second conductivity type impurity may be of different conductivity types.

In the head-mounted display apparatus according to some embodiments of the present disclosure, the first conductivity type impurity may include n-type impurities including phosphorus (P), arsenic (AS), or antimony (Sb), and the second conductivity type impurity may include p-type impurities including boron (B), aluminum (Al), gallium (Ga), or indium (In).

In the head-mounted display apparatus according to some embodiments of the present disclosure, the diode type bank may further include a first depletion area of a first width disposed in a boundary area between the first semiconductor layer and the second semiconductor layer.

Although embodiments of the present disclosure have been described with reference to the accompanying drawings, the present disclosure is not limited to the above embodiments but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A display device comprising:
a substrate including a light-emissive area and a non-light-emissive area;
a diode type bank located on the non-light-emissive area and constructed to separate a plurality of sub-pixels from each other;
a light-emitting element disposed in each of the plurality of sub-pixels; and
an encapsulation portion disposed on the light-emitting element.

2. The display device of claim 1, wherein the diode type bank includes an opaque semiconductor material.

3. The display device of claim 1, wherein the diode type bank includes a first semiconductor layer and a second semiconductor layer disposed on the first semiconductor layer.

4. The display device of claim 3, wherein the first semiconductor layer includes amorphous silicon doped with a first conductivity type impurity, and the second semiconductor layer includes amorphous silicon doped with a second conductivity type impurity,
wherein the first conductivity type impurity and the second conductivity type impurity are of different conductivity types.

5. The display device of claim 4, wherein the first conductivity type impurity includes n-type impurities including phosphorus (P), arsenic (AS), or antimony (Sb),
wherein the second conductivity type impurity includes p-type impurities including boron (B), aluminum (Al), gallium (Ga), or indium (In).

6. The display device of claim 4, wherein each of the first semiconductor layer and the second semiconductor layer has a lower density than a density of polycrystalline silicon or single crystalline silicon.

7. The display device of claim 4, wherein each of the first semiconductor layer and the second semiconductor layer has a light transmittance lower than 5%.

8. The display device of claim 1, wherein the light-emitting element includes:
a first electrode overlapping the light-emissive area and having an edge covered by the diode type bank;
an organic light-emitting layer disposed on the first electrode; and
a second electrode disposed on the organic light-emitting layer.

9. The display device of claim 8, wherein the diode type bank includes:
a first semiconductor layer having a portion overlapping an edge of the first electrode, wherein the first semiconductor layer is doped with a first conductivity type impurity;
a second semiconductor layer disposed on the first semiconductor layer and doped with a second conductivity type impurity different from the first conductivity type impurity; and
a first depletion area of a first width disposed in a boundary area between the first semiconductor layer and the second semiconductor layer.

10. The display device of claim 9, wherein the first conductivity type impurity includes n-type impurities, and the second conductivity type impurity includes p-type impurities.

11. The display device of claim 9, wherein the diode type bank is disposed between the first electrode receiving a positive (+) voltage and the second electrode receiving a negative (−) voltage,
wherein the diode type bank includes a second depletion area between the first semiconductor layer and the second semiconductor layer, the second depletion region having a second width greater than first width of the first depletion region, and wherein no current flows in the second depletion area.

12. A head-mounted display apparatus comprising:
a display device;
a case for accommodating the display device therein; and
a lens array disposed at one side of the case and configured to display an image output from the display device,
wherein the display device includes:
a substrate including a light-emissive area and a non-light-emissive area;
a diode type bank located on the non-light-emissive area and constructed to separate a plurality of sub-pixels from each other;
a light-emitting element disposed in each of the plurality of sub-pixels; and
an encapsulation portion disposed on the light-emitting element.

13. The head-mounted display apparatus of claim 12, wherein the diode type bank includes a first semiconductor layer and a second semiconductor layer disposed on the first semiconductor layer.

14. The head-mounted display apparatus of claim 13, wherein the first semiconductor layer includes amorphous silicon doped with a first conductivity type impurity, and the second semiconductor layer includes amorphous silicon doped with a second conductivity type impurity,
wherein the first conductivity type impurity and the second conductivity type impurity are of different conductivity types.

15. The head-mounted display apparatus of claim 14, wherein the first conductivity type impurity includes n-type impurities including phosphorus (P), arsenic (AS), or antimony (Sb),
wherein the second conductivity type impurity includes p-type impurities including boron (B), aluminum (Al), gallium (Ga), or indium (In).

16. The head-mounted display apparatus of claim 14, wherein the diode type bank further includes a first depletion area of a first width disposed in a boundary area between the first semiconductor layer and the second semiconductor layer.
